(19) United States
(12) Patent Application Publication
(10) Pub. No.: US 2023/0325548 A1
(43) Pub. Date: Oct. 12, 2023

(54) MACHINE LEARNING-BASED DESIGN OF BEAM-BASED PHYSICAL STRUCTURES

(71) Applicant: Siemens Industry Software Inc., Plano, TX (US)

(72) Inventor: Ricky Rodgers, Chesterfield, MO (US)

(73) Assignee: Siemens Industry Software Inc., Plano, TX (US)

(21) Appl. No.: 18/042,338

(22) PCT Filed: Aug. 31, 2020
(86) PCT No.: PCT/US2020/048764

§ 371 Date: Feb. 21, 2023

(51) Int. Cl. G06F 30/13; G06F 30/27

(52) U.S. Cl. CPC G06F 30/13; G06F 30/27

(57) ABSTRACT

A computing system may include a design space access engine configured to access a design space of a physical structure. The computing system may also include a structural design engine configured to encode the design space into a set of 3-dimensional (3D) rectangles. Each 3D rectangle may define candidate beam locations in the physical structure and candidate beam locations of the 3D rectangles may be defined by lines between vertex pairs of each 3D rectangle. The structural design engine may also provide the encoded design space as an input to a machine-learning (ML) model, generate, through the ML model, a design of the physical structure based on the encoded design space, and provide the design of the physical structure in support of manufacture of the physical structure.

### BACKGROUND

Modern computer systems can be used to create, use, and manage data for products and other items. Computer-aided technology (CAx) systems, for instance, may be used to aid in the design, analysis, simulation, or manufacture of products. Examples of CAx systems include computer-aided design (CAD) systems, computer-aided engineering (CAE) systems, visualization and computer-aided manufacturing (CAM) systems, product data management (PDM) systems, product lifecycle management (PLM) systems, and more. These CAx systems may include components (e.g., CAx applications) that facilitate the design and simulated testing of product structures and product manufacturing processes.

### BRIEF DESCRIPTION OF THE DRAWINGS

Certain examples are described in the following detailed description and in reference to the drawings.

FIG. 1 shows an example of a computing system that supports machine learning (ML)-based structural designs of beam-based physical structures.

FIG. 2 shows an example ML-based design of a framework layout for a physical structure via an encoded design space.

FIG. 3 shows an example of ML-based determinations of beam classifications for a physical structure design.

FIG. 4 shows an example of ML-based determinations of offset or rotation values for beams of a physical structure design.

FIG. 5 shows an example of ML-based determinations of end-cut classifications for a physical structure design.

FIG. 6 shows an example training of an ML model by the structural design engine.

FIG. 7 shows an example of logic that a system may implement to support ML-based structural design.

FIG. 8 shows an example of a computing system that supports ML-based structural design.

### DETAILED DESCRIPTION

The discussion herein refers to physical structures, including beam-based physical structures. Beam-based physical structures may refer to any structure that comprises beams, and beams may include any linear structural element. Beams may provide a frame structure for various products, building structures, and the like, and beams may be used in a design as load bearing or shape-defining elements, or for various other purposes. As one example, steel beam frame structures can be used in building frames, platforms, access ways, or any number of other physical structures.

Design of beam-based physical structures can be complicated. For example, the design of steel frame structures and other beam-based physical structures may require domain experts, knowledgeable in the art and science of laying out beam frames to meet load requirements trimming and uniting rigid steel members in order to meet strength, cost, usage and maintenance requirements, and other required beam-based design expertise. Modern CAD tools may require such domain experts to perform many repetitive and tedious tasks to produce satisfactory designs of a beam-based physical structure. While CAD tools may provide the capability to create complex geometrical features that form a beam-based physical structure, current CAD systems may provide little or no guidance as how to actually generate beam layouts, determine end-cut parameters, and produce multiple other design components of beam-based physical structures with desired strength, cost, and usage attributes.

The disclosure herein may provide systems, methods, devices, and logic for ML-based structural design. As described in greater detail herein, various features are presented to support generation of structural designs of beam-based physical structures through machine-learning. The described ML-based structural design features may support the design of physical structures through ML-based generation of framework layouts, beam classifications, offset or rotation values, end-cut assignments, or various other design components of a beam-based physical structure design. The ML-based structural design features described herein may also utilize encoded design spaces to represent beam-based structure designs, including encoding of candidate and determined beam locations in a design space. Such an encoded design space may be sparsely defined and encoded with various design elements, parameters, and features of a physical structure design. In that regard, the encoded design spaces described herein need not encode each individual point or voxel of a CAD coordinate system used to model physical structure designs. In doing so, the encoded design space features of the present disclosure may greatly reduce the amount of data provided, processed, learned, and applied by ML models. As such, the ML-based structural design features described herein may provide improved computational speed and reduce processing latencies as compared to traditional design processes or other brute force computational and ML-based design techniques.

These and other ML-based structural design features and technical benefits are described in greater detail herein.

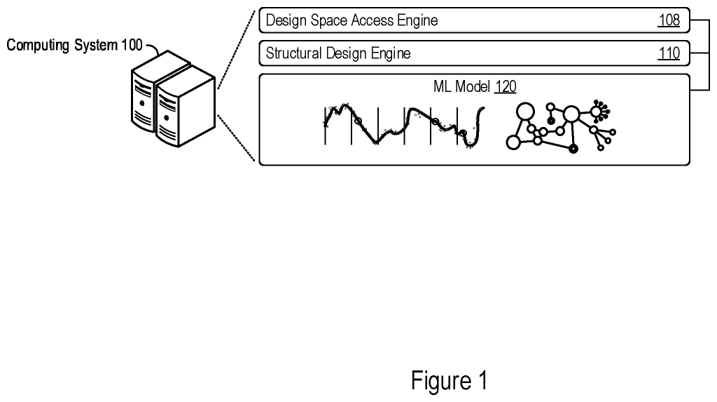

FIG. 1 shows an example of a computing system 100 that supports generation of ML-based structural designs of beam-based physical structures. The computing system 100 may take the form of a single or multiple computing devices such as application servers, compute nodes, desktop or laptop computers, smart phones or other mobile devices, tablet devices, embedded controllers, and more. In some implementations, the computing system 100 implements a CAx tool, application, or program to aid users in the design, analysis, simulation, or 3D manufacture of physical structures.

As an example implementation to support any combination of the ML-based structural design features described herein, the computing system 100 shown in FIG. 1 includes a design space access engine 108 and a structural design engine 110. The computing system 100 may implement the engines 108 and 110 (including components thereof) in various ways, for example as hardware and programming. The programming for the engines 108 and 110 may take the form of processor-executable instructions stored on a non-transitory machine-readable storage medium and the hardware for the engines 108 and 110 may include a processor to execute those instructions. A processor may take the form of single processor or multi-processor systems, and in some examples, the computing system 100 implements multiple engines using the same computing system features or hardware components (e.g., a common processor or a common storage medium).

In the example shown in FIG. 1, the computing system 100 also includes a machine-learning model 120. The computing system 100 may itself implement the ML model 120 or, in some implementations, remotely access the ML model 120. The ML model 120 may implement or support any number of machine-learning capabilities, algorithms, techniques, or processes in support of physical structure design. For instance, the ML model 120 may implement any number of supervised, semi-supervised, unsupervised, or reinforced learning models to generate physical structure designs or any design components thereof. As illustrative examples, the ML model 120 may utilize Markov chains, context trees, support vector machines, convolutional neural networks, Bayesian networks, or various other machine learning components, techniques, or algorithms to interpret existing designs of beam-based physical structures and subsequently generate structure designs, create structural frameworks, determine design parameters, or otherwise support the design of beam-based physical structures. As a continuing example herein, training and application of the ML model 120 is discussed in the context of the design space access engine 108 and the structural design engine 110.

In operation, the design space access engine 108 may access a design space of a physical structure. In operation, the structural design engine 110 may encode the design space into a set of 3-dimensional (3D) rectangles, and each 3D rectangle may define candidate beam locations in the physical structure and the candidate beam locations in the 3D rectangles may be defined by lines between vertex pairs of each 3D rectangle. The structural design engine 110 may also provide the encoded design space as an input to the ML model 120 and generate, through the ML model 120, a design of the physical structure based on the encoded design space. The design of the physical structure may include beams at beam locations determined by the ML model 120 from the candidate beam locations. The structural design engine 110 may further provide the design of the physical structure in support of manufacture of the physical structure.

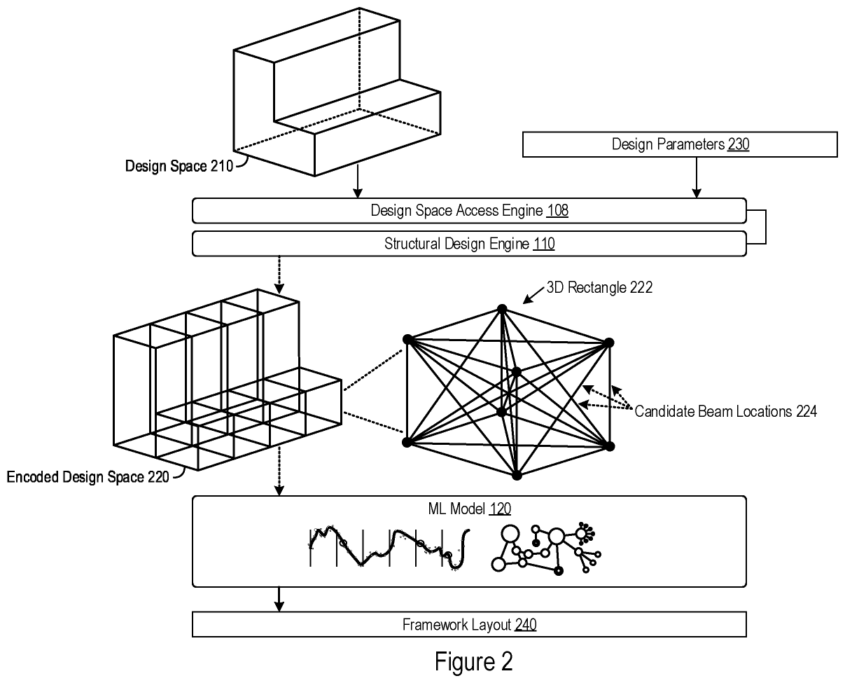

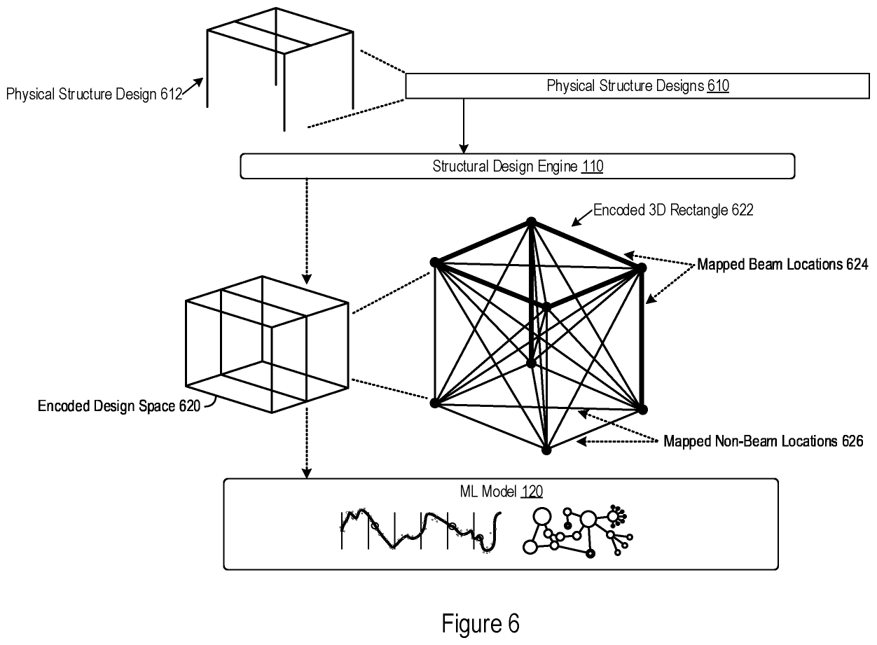

These and other ML-based structural design features are described in greater detail herein. Example features in applying ML models in support of physical structure design are described next in connection with FIGS. 2-5 and example ML-model training features are later described in connection with FIG. 6.

FIG. 2 shows an example ML-based design of a framework layout for a physical structure via an encoded design space. In the example of FIG. 2, an illustrative computing system is presented through the design space access engine 108 and the structural design engine 110. Any other system implementations of the ML-based structural design features described herein are contemplated as well.

In the example shown in FIG. 2, the design space access engine 108 accesses a design space 210. A design space may refer to any bounded space used for the design, modeling, or generation of a CAD physical structure. Some CAD applications may implement design spaces as bounding boxes, and the design space access engine 108 may obtain the design space 210 as a user-specified input delineating the boundaries, volume, area, or other spatial characteristics of a physical structure design. As another example, the design space access engine 108 may access the design space 210 as a template or preconfigured bounding space from a design repository of beam-based physical structure designs. For instance, CAD applications may include templated design areas for different types or classes of physical structures, and the design space access engine 108 may access a preconfigured design space accordingly. As yet another example, the design space access engine 108 may obtain the design space 210 as a bounding volume that encloses a preexisting physical structure design, using such a bounding volume as a starting point for the design of a different physical structure (e.g., a next version of the physical structure).

The design space 210 accessed by the design space access engine 108 may represent a 3D volume within which elements of a physical structure design can be positioned or occupy. The structural design engine 110 may implement ML-based design capabilities to generate a beam-based physical structure design for the design space 210 or generate, determine, or produce selected design components of the physical structure design. In doing so, the structural design engine 110 may access the ML model 120, and the ML model 120 may be configured to learn structural design techniques, parameters, and elements through learning from training sets of existing physical structures. In particular, the structural design engine 110 and ML model 120 may support design of beam-based physical structures. As noted herein, beam-based physical structures may refer to any physical structure comprised of or including beams (e.g., linear structural elements). In some implementations, the structural design engine 110 may utilize the ML model 120 in the generation of framework layouts comprised of determined beam locations in the design space 210, beam classifications (e.g., as differentiated based on cross-section shape or other structural characteristics), beam offset or rotation values, end-cut classifications, end-cut or joint parameters, and more.

To support ML-based structural designs, the structural design engine 110 may transform the design space 210 into an encoded design space. Modern CAD systems may represent a design space through a 3D coordinate system, space voxelizations, or depth maps. To support increased granularity and precision, the design space for even a relatively small physical structure may include an immense number of discrete points. ML-based training and processing of high precision design spaces may require immense amounts of computing power and processing time. As such, providing all of the 3D points in a design space 210 as an input into the ML model 120 may overwhelm the ML learning processes applied by the ML model 120. By encoding the design space 210 into a sparser representation, the structural design engine 110 may reduce the number of input points or input values used to represent the design space 210 for a beam-based physical structure and ML-based processing of such a design.

Encoded design spaces generated by the structural engine 110 may provide a capability to uniquely represent beam locations in a design space, including candidate beam locations in an empty design space and determined beam locations selected be included in a physical structure design. To illustrate, the structural design engine 110 may encode the design space 210 to represent candidate beam locations in the design space 210. To do so, the structural design engine 110 may encode the design space 210 into a set of 3D rectangles, and each 3D rectangle of an encoded design space may define candidate beam locations in the physical structure, for example through a beam lattice defined for each 3D rectangles. The structural design engine 110 may define candidate beam locations of a 3D rectangle as the lines between vertex pairs of the 3D rectangle. A given 3D rectangle in an encoded design space may include eight (8) vertices, and the structural design engine 110 may thus define up to twenty-eight (28) different candidate beam locations in the given 3D rectangle, e.g., as some or all of the twenty-eight (28) lines between vertex pairs of the given 3D rectangle.

In generating an encoded design space, the structural design engine 110 may partition a design space into any number of such 3D rectangles, and the partitioned design space may form a 3D grid comprised of the 3D rectangles. In some implementations, the structural design engine 110 partition a design space into a 3D grid comprised of a predetermined number of 3D rectangles, which may vary based on the dimensions of the design space, the type of physical structure the design space applies to, custom user-specified parameters or inputs, or according to any number of additional or alternative partitioning parameters. Note that the structural design engine 110 may encode a design space with 3D rectangles of differing size or volume, which may also vary based on a shape or volume of the design space in which the 3D rectangles are encoded within.

In the example in FIG. 2, the structural design engine 110 encodes the design space 210 into 3D rectangles to generate the encoded design space 220. The encoded design space 220 as illustrated in FIG. 2 includes eight (8) different 3D rectangles, including 3D rectangles of differing height (and thus differing volume). As also shown in FIG. 2, an illustrative example of a given 3D rectangle in the encoded design space 220 is shown as the 3D rectangle 222. For the 3D rectangle 222, the structural design engine 110 may specify candidate beam locations 224 as lines between vertex pairs of the 3D rectangle 222. (Note that for visual clarity, only three (3) of the candidate beam locations 224 defined in the 3D rectangle 222 are labeled via dotted arrows.)

For 3D rectangles of an encoded design space, the structural design engine 110 may define candidate beam locations through partially or fully-connected lattice structures. For the 3D rectangle 222 shown in FIG. 2, the structural design engine 110 defines the 3D rectangle 222 as a fully connected lattice structure in which candidate beam locations 224 are defined between all vertex pairs of each 3D rectangle 222. For partially-connected lattice structures, the structural design engine 110 may define candidate beam locations as some, but not all, of the lines between vertex pairs of the 3D rectangle. For instance, the structural design engine 110 may define candidate beam locations in a 3D rectangle as the vertex pair lines along the outer volume or surface of the 3D rectangle, but not the vertex pair lines that pass through the interior volume of the 3D rectangle.

In generating an encoded design space, the structural design engine 110 may uniquely represent beam locations in a design space, whether as candidate beam locations to potentially include a design or subsequently determined beams to include in a physical structure design. The structural design engine 110 may assign unique identifiers for beam locations in a design space, which may be referred to herein as beam location identifiers. Through beam location identifiers, the encoded design space may specify further characteristics, parameters, or attributes of corresponding beams, including whether the beam location corresponds to a candidate beam location, a determined beam location to include in the physical structure design, design parameters of beams at the determined beam locations (e.g., beam type, offset values, etc.), and the like.

Prior to determination of a framework layout, the structural design engine 110 may assign beam location identifiers for each of the candidate beam locations of an encoded design space. For 3D rectangles defined with fully connected lattice structures, the structural design engine 110 may assign twenty-eight (28) beam location identifiers, one for each candidate beam location in a given 3D rectangle. Since the surface of 3D rectangles may overlap in a rectangularly partitioned design space, the structural design engine 110 assign the same beam location identifier to candidate beam locations of different 3D rectangles that wholly overlap or are identical. To further illustrate, 3D rectangles in an encoded design space may share common vertices, and an identical vertex pair in the encoded design space may be part of two different rectangles. In such cases, the structural design engine 110 may assign the same beam location identifier to the candidate beam location of this vertex pair part of multiple 3D rectangles.

In any of the ways described herein, the structural design engine 110 may identify beam locations in an encoded design space. Through beam location identifiers, encoded design spaces may encode additional data about beam locations (whether as candidate beam locations or later determined beam locations for the physical structure). Attributes of beam locations may encoded through any number of various flags, tags, or values associated with a beam location identifier. For instance, selected beams to be included in the design of physical structure may be encoded by setting an included beam tag for the corresponding beam location identifier. Other ML-determined design components can also be specified in encoded design spaces in a similar manner, e.g., for beam classifications, offset or rotation values, end-cut classifications, and the like. Such features are described in greater detail herein, and any such data may be appended to, tied with, or encoded with beam location identifiers to specify design features or parameters for a physical structure design.

For an encoded design space, the structural design engine 110 may provide a capability for user-inputs to select specific candidate beam locations to include or exclude in a physical structure design. For instance, the structural design engine 110 may identify specific columns or rows of 3D rectangles partitioned from a design space to include in the encoded design space, and include the candidate beam locations in these selected columns and/or rows for consideration by the ML model 120. Lattices of non-selected 3D rectangles may be excluded or not set as candidate beam locations in the encoded design space.

The structural design engine 110 may provide an encoded design space as an input to the ML model 120, which may include beam locations defined by the structural design engine 110 for consideration. As noted herein, an encoded design space may provide a sparse representation of the design space of a physical structure, by representing beam locations instead of all 3D points or voxels in the design space. For an encoded design space partitioned by the structural design engine 110 into a 3D grid of rectangles, unique beam locations may be represented instead of 3D points or voxels. As such, encoded design spaces for beam-based physical structures may be represented by much smaller amount of data as compared to 3D coordinate systems.

As an illustrative example of data compression benefits provided by the described encoded design spaces described herein, traditional 3D encoding or voxelization of even a modest-sized platform structure could occupy a 15-foot cubic space. At a resolution of 1.0 inches/voxel, such a voxel-based design space would result in 5,832,000 input values for the design space. In comparison, the structural design engine 110 may generate an encoded design space for the platform structure through a 3D grid of partitioned 3D rectangles (of varying size), with a few thousand beam locations represented in the encoded design space. In this illustration, encoded design spaces that uniquely represent beam locations may result in 99%+ reductions in input values, and may provide benefits in terms of memory requirements and resource consumption. The encoded design space features described herein may improve the speed of ML-based processing of inputs, supporting generation of physical structure designs with increased efficiency and reduced resource consumption.

In some implementations, the structural design engine 110 may provide additional inputs to an ML model besides an encoded design space, which may help guide the ML model 120 in specific design considerations. Example design parameters that the structural design engine 110 may provide to the ML model 120 include force values applicable to a physical structure (e.g., at specific locations in the physical structure design), a structure type, or a combination of both. In the example shown in FIG. 2, the design space access engine 108 obtains the design parameters 230 that may be applicable to the physical structure being designed in the design space 210, and the structural design engine 110 may provide both the encoded design space 220 and the design parameters 230 as inputs to the ML model 120.

The ML model 120 may be configured to analyze inputs in the form of encoded design spaces and design parameters and generate physical structure designs for the provided inputs. In the example shown in FIG. 2, the ML model 120 generates the framework layout 240 from the encoded design space 220. The framework layout 240 may be one example of a design of a physical structure that the structural design engine 110 may generate through the ML model 120. A framework layout may refer to any representation of determined beam locations for a physical structure, which the ML model 120 may determine from the candidate beam locations specified in an encoded design space. The framework layout 240 generated in FIG. 2 may account for the candidate beam locations defined in the encoded design space 220 as well as any applied force values, physical structure type, or other considerations specified in the design parameters 230.

In some examples, the ML model 120 generates the framework layout 240 via computed probability values. The ML model 120 may generate beam probability values for each of the candidate beam locations in the encoded design space 220, and such beam values may be normalized, e.g., along a scale of 0.0-1.0 (inclusive). A ML-generated beam probability value for a particular candidate beam location (and thus for a particular beam location identifier) may represent a classification value or probability value that a beam at the particular candidate beam location should be included in the design of the physical structure. The structural design engine 110 may determine to include a beam in a physical structure design at the candidate beam locations with beam values that exceed a selection threshold (e.g., are greater than 0.9). In that regard, the framework layout 240 may include determined beam locations at each candidate beam location with a ML-generated beam value that exceeds the configured selection threshold.

In some implementations, the structural design engine 110 encodes determined beam locations into an encoded design space. For example, the structural design engine 110 may represent the framework layout 240 by further encoding the encoded design space 220 with determined beam locations. Beam location identifiers in an encoded design space may be configured to include an included beam flag, and the structural design engine 110 may set the included beam flag to a predetermined value (e.g., value of 1) for determined beam locations in the physical structure design. The structural design engine 110 may further set the included beam flag for candidate beam locations not determined to include a beam (e.g., with a computed beam probability value below the selection threshold) to a different value (e.g., value of 0). As such, a framework layout may maintain the 3D rectangular grid of an encoded design space and further denote which particular beam locations are determined to be included beams in the design of a physical structure.

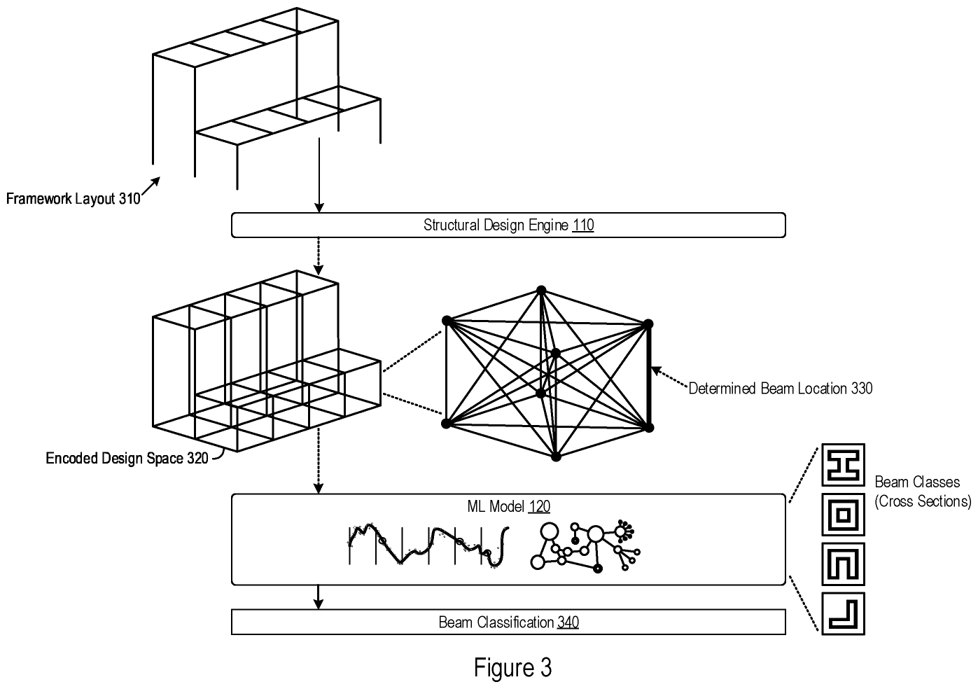

As such, the structural design engine 110 may generate (through the ML model 120) a framework layout of a physical structure for a given design space, and the framework layout may identify beams at selected beam locations in the given design space. Such a ML-generated framework layout may be output as a first design step in generation of a physical structure design, and the structural design engine 110 may generate any number of additional or alternative design components for the physical structure. One such example is beam classifications for a design of beam-based physical structure, and beam classifications are described next in connection with FIG. 3.

FIG. 3 shows an example of ML-based determinations of beam classifications for a physical structure design. In FIG. 3, the structural design engine 110 accesses a framework layout 310 for a physical structure. The framework layout 310 may be the framework layout 240 generated by the structural design engine 110 as described in FIG. 2, a user-designed framework layout, or a user-modified version of the framework layout 240 generated by the structural design engine 110 (e.g., to effectuate user-specific edits to the framework layout 240 generated via the ML model 120).

The structural design engine 110 may support classification of the beams included in the framework layout 310. Beam classification may refer to any process by which a beam class is assigned to a beam of a physical structure design, and beam classifications may include determining a specific beam shape (based on a beam cross section) for the beams of the framework layout 310. Example beam classes may thus differ based on cross-section shapes, and include T-shaped, ‘O’-shaped, ‘n’-shaped, or ‘L’-shaped cross sections (among many others). Additionally or alternatively, beam classes may differ based on beam materials (steel (including different steel grades), plastic, iron, composites, wood, etc.), strength or load-bearing characteristics, cost, supply availability, user-specified delineations, or any other beam characteristic by which beams can be differentiated.

In generating beam classifications for a physical structure design, the structural design engine 110 may generate an encoded design space 320 from the framework layout 310, doing so any of the ways described herein. In example of FIG. 3, the structural design engine 110 encodes the framework layout 310 into the encoded design space 320. When the framework layout 310 is generated by the ML model 120 (e.g., using the encoded design space 220 as an input), the structural design engine 110 may maintain the same 3D rectangle partitioning of the design space 210, e.g., by maintaining the beam location identifiers included in the encoded design space 220 or framework layout 240. The encoded design space 320 for the framework layout 310 may specify which beams included the encoded design space 320 to classify (e.g., by setting a classifier tag associated with beam location identifiers of each beam included in the framework layout 310). In some implementations, the structural design engine 110 configures the encoded design space 320 to classify for each of the determined beam locations of the physical structure design (e.g., for each beam location identifier with an included beam tag set to a predetermined value).

In the example shown in FIG. 3, the encoded design space 320 generated by the structural design engine 110 includes a determined beam location 330. The structural design engine 110 may mark a beam at the determined beam location 330 for classification by setting a classifier tag for the beam location identifier assigned to the determined beam location 330. The ML model 120 may take the encoded design space 330 as an input and generate the beam classification 340. In some implementations, the structural design engine 110 may also provide design parameters as inputs to the ML model 120 for beam classifications, including as examples applied force values on the framework layout 310, structure type, and the like. The beam classification 340 generated by the ML model 120 may assign a specific beam class to each of the determined beam locations specified in the encoded design space 320.

In such a way, the structural design engine 110 and the ML model 120 may support ML-based determination of beam classifications (e.g., cross section shapes) for beams included in a physical structure design. The structural design engine 110 may encode the determined beam classifications 340 into an encoded design space, e.g., by assigning classification values to the beams included in the framework layout 240. Classification values may be implemented as one-hot encoding values in some implementations, and the structural design engine 110 engine may append such classification values to beam location identifiers of the determined beam locations in the design.

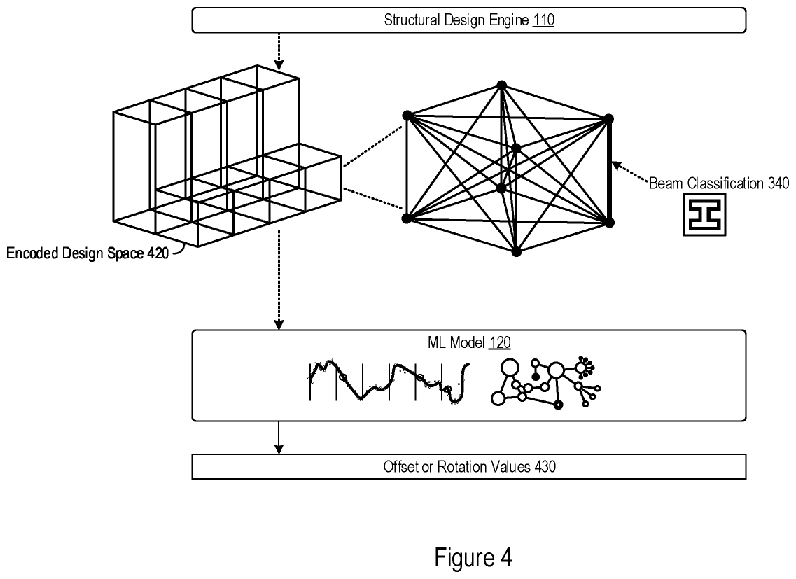

Beam classifications may be one example of a design of a physical structure that the structural design engine 110 may generate. Additional or alternative design components for the physical structure may be generated by the structural design engine 110, such as offset or rotation values as described next in connection with FIG. 4.

FIG. 4 shows an example of ML-based determinations of offset or rotation values for beams of a physical structure design. In FIG. 4, the structural design engine 110 accesses an encoded design space 420 for a physical structure. The structural design engine 110 may generate or access the encoded design space 420 from a framework layout or encoded design space encoded with beam classifications (e.g., as described in FIG. 3).

The structural design engine 110 may support determination of offsets and rotations for beams included in the encoded design space 420. Offsets and rotations may refer to any beam parameters for which a given beam aligns to a neighboring beam in the design of the physical structure, and may depend on the shape of the particular beams being aligned. The structural design engine 110 may provide the encoded design space 420 and any number of design parameters as inputs to the ML model 120. As seen in FIG. 4, beams in the encoded design space 420 may be encoded with beam classifications, such as the beam classification 340 for a particular beam at a determined beam location.

In some implementations, the structural design engine 110 may select a subset of beams included in the encoded design space 420 for offset and rotation value determination. Such selection may be user-based or according to any number of selection criteria (e.g., longest beams, beams bearing the great load, based on applied force value analyses, and the like). The ML model 120 may generate offset or rotation values 430 for the beams of the encoded design space 420 (or any selected subset thereof).

Note that the offset or rotation values 430 generated by the ML model 120 may be inexact. In some implementations, the ML model 120 generates offset or rotation values 430 for the encoded design space 420 as a reference range of offsets or rotation values. The structural design engine 110 may implement supplemental capabilities to access the reference ranges as well as actual beam dimensions and location data of different beams to compute the exact offset and rotation values for the beams in the design of the physical structure.

In such a way, the structural design engine 110 and the ML model 120 may support ML-based determination of offset and rotation values 430. The structural design engine 110 may encode determined offset and/or rotation values into an encoded design space, e.g., by assigning offset and rotation values to the beams included in the encoded design space 420. Rotation and offset values may be implemented as numerical values encoded for or otherwise associated with beams of an encoded design space (e.g., associated with a particular beam location identifier).

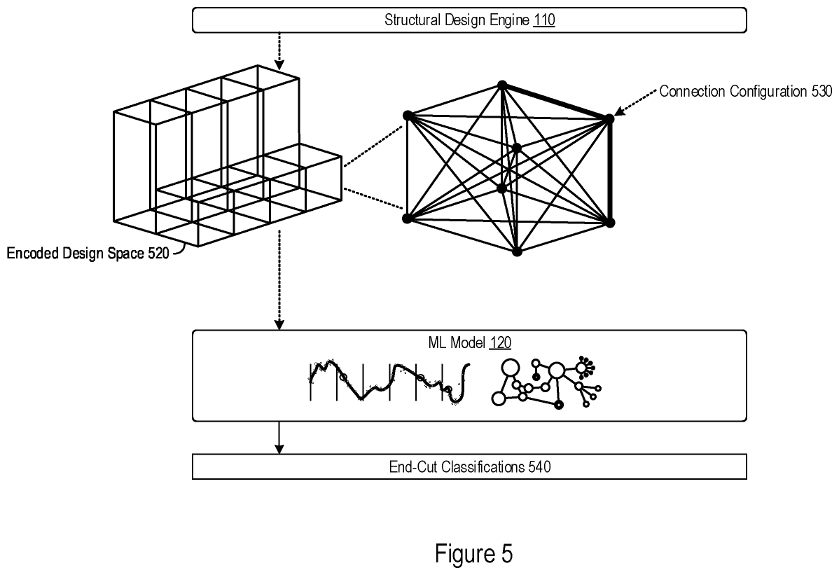

FIG. 5 shows an example of ML-based determinations of end-cut classifications for a physical structure design. In FIG. 5, the structural design engine 110 accesses an encoded design space 520 for a physical structure. The structural design engine 110 may generate or access the encoded design space 520 as an encoded design space encoded with offset and rotation values (e.g., as described in FIG. 4).

In determining end-cut classifications, the structural design engine 110 may identify connection points between different beams in the encoded design space 520. As the encoded design space 520 may comprise offset and rotation values for beams of the physical structure design, the structural design engine 110 may use the ML model 120 to determine end-cut classifications for the physical structure design. An end-cut classification may refer to any classification value to differentiate between different types of cuts to apply to the end of beams to join with adjacent beams at intersecting corners or support locations. The effectiveness of end cutting beams of a physical structure may depend on strength requirements of the physical beams and relative orientations (e.g., rotation and offset) of intersecting beams. Specific joining methods between beams may also be considered, including whether welding gaps or bolts will be used, which may result in different end-cut classifications and parameters.

To support ML-based end-cut classifications, the structural design engine 110 may generate connection configurations for the connection points between beams of the encoded design space 520. In FIG. 5, the structural design engine 110 generates a connection configuration 530 for the intersection point at which two beams interconnect in the encoded design space 520. The structural design engine 110 may generate a connection configuration as a multi-dimensional grid, including dimensions which define relative 3D locations of the beams intersecting (e.g., attached) at the connection point, values for the offset and rotation values (e.g., normalized) of the intersecting beams, and beam classifications of the intersecting beams. The connection configuration may also represent the attachment point of the intersecting beams. In that regard, a connection configuration may represent various beam parameters of the beams that intersect at a given connection point in the encoded design space 520.

The structural design engine 110 may provide, as an input to the ML model 120, connection configurations for each of the beam intersections in the encoded design space 520. Based on the input connection configurations, the ML model 120 may determine end-cut classifications 540 to apply to each beam intersection. Note that the ML model 120 may determine that no end cut is necessary for intersecting beams, and “no end-cut” may be a particular end-cut class included in the end-cut classifications 540. In some implementations, the end-cut classifications 540 may include end cut parameters to apply in the cuts. Such cut parameters may include tool parameters applicable to a specific end-type class determined by the ML model 120 to join beam intersections in the encoded design space 520. Such tool parameters may require tool parameters (e.g., tool body, length, weight, height, cylinder radius values, etc.), which the structural design engine 110 may provide to the ML model 120 for specific end-cut classifications.

In such a way, the structural design engine 110 and the ML model 120 may support ML-based determination of end-cut classifications. The structural design engine 110 may encode determined end-cut assignments (including end-cut parameters applicable and determined for specific end-cut classes) into an encoded design space.

In any of the ways described herein, the ML-based structural designs may be implemented. Example designs (or design components) contemplated herein include framework layouts, beam classifications, offset and rotation values, end-cut classifications, and more. The structural design engine 110 may apply the ML model 120 to determine any combination of such elements of a design of a physical structure, which the structural design engine 110 may determine serially. At any point, the structural design engine 110 accept user inputs to modify or customize a ML-generated design, whether by modifying a ML-generated framework layout, altering offsets, changing ML-defined beam classifications, and the like. As such, the ML-based structural design features described herein may flexibly combine ML-based expertise learned from existing models with user-specific configurations.

Any of the described ML-based structural features may be supported through encoded design spaces, by which the structural design engine 110 may reduce the volume of input data provided to a ML model 120. By doing so, the structural design engine 110 may reduce computational strain in ML-based structural designs, and input design spaces may be reduced by more than 99%, which can result in significant speed and performance improvements while maintaining design accuracy for beam-based physical structures. The encoded design space features for further support subsequent encoding of beam data generated during different phases of a design process, allowing the ML-based structure design features to apply ML-based determinations for any number of different design components across any number of design steps, doing so at increased computational efficiency.

FIG. 6 shows an example training of the ML model 120 by the structural design engine 110. The structural design engine 110 may train the ML model 120 using existing beam-based physical structure designs, and do so such that the ML model 120 can learn and generate any number of design components for any phase of the design process for beam-based physical structures.

In training the ML model 120, the structural design engine 110 may access a set of physical structure designs 610. The physical structure designs 610 may be accessed from a CAD or design repository, and may include any number of previously-designed beam-based physical structures. In the example of FIG. 6, the physical structure designs 610 includes a physical structure design 610, which is used as a continuing illustrative example in how the structural design engine 110 may train the ML model 120 to support any of the ML-based structural design features contemplated herein.

For the physical structure design 612 (and any of the other physical structure design in the physical structure designs 612), the structural design engine 110 may generate an encoded design space 620 for the physical structure design 612. In doing so, the encoded design space 620 for the physical structure design 612 may include encoded 3D rectangles, such as the encoded 3D rectangle 622 illustrated in FIG. 6. The encoded 3D rectangles of the encoded design space 620 may map to different portions of the physical structure design 612, and each encoded 3D rectangle may define possible beam locations in a design space of the physical structure design 612. Moreover, each encoded 3D rectangle in the encoded design space 620 may encode which of the possible beam locations map to beams in the physical structure design 612 and which of the possible beam locations do not map to any beams in the physical structure design 612.

In the example shown in FIG. 6, the encoded 3D rectangle 622 includes mapped beam locations 624 for actual beams in the physical structure design 612 as well as mapped non-beam locations 626 at possible beam locations of the encoded 3D rectangle 622 at which no beams of the physical structure design 612 are located. The structural design engine 110 may generate the encoded design space 620 for the physical structure design 612 in any of the forms described herein, e.g., assigning beam location identifiers and setting beam location flags to a value of ‘1’ for beam location identifiers corresponding to the mapped beam locations 624 and to a value of ‘0’ for the beam location identifiers corresponding to the non-mapped beam locations 626.

In generating the encoded design space 620, the structural design engine 110 may further extract structure data from the physical structure design 612. Example structure data that the structural design engine 110 may extract from the given physical structure design 612 includes a beam classification for each of the beams in the physical structure design 612, offset or rotation values to interconnect the beams in the physical structure design 612, end-cut classifications to applied at connection points between the beams in the physical structure design 612, or any combination thereof. That is, the structural design engine 110 may extract any relevant data used to generate the various design components described herein for beam-based physical structure designs, and encode extracted structure data in the encoded design space 620 accordingly.

Additionally or alternatively, the structural design engine 110 may extract various design parameters of the physical structure design 612, including any design parameters the ML model 120 is configured to account for in generating designs of physical structures. Example of such design parameters included applied force values for the physical structure design 612 and a structure type of the physical structure design 612. Structure types may defined according to any classification scheme, and may allow the ML model 120 to differentiate between different types of physical structures in applied learning processes. Through structure type labeling, the ML model 120 may be trained to learn different design components, parameters, layouts, and aspects of different types of physical structures, which may increase the accuracy at which ML model 120 can learn from training data and generate designs from input data.

In some sense, the structure data, beam data, and design parameters extracted from existing designs may serve as labels for training data comprised of encoded design spaces. As such, the structural design engine 110 may provide the encoded design space 620 as training data for the ML model 120, and the ML model 120 may, for example, apply any number of supervised learning techniques to learn from the encoded design spaces. In such a manner, the structural design engine 110 may train a ML model 120 as part of or in support of any of the ML-based structural design features described herein.

In any of the ways described herein, ML-based structural designs may be implemented. While many ML-based structural design features have been described herein through illustrative examples presented through various figures, the design space access engine 108 and the structural design engine 110 may implement any combination of the ML-based structural design features described herein.

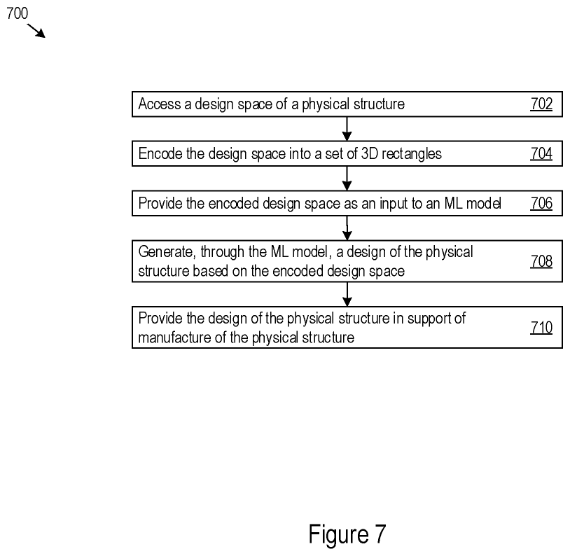

FIG. 7 shows an example of logic 700 that a system may implement to support ML-based structural design. For example, the computing system 100 may implement the logic 700 as hardware, executable instructions stored on a machine-readable medium, or as a combination of both. The computing system 100 may implement the logic 700 via the design space access engine 108 and the structural design engine 110, through which the computing system 100 may perform or execute the logic 700 as a method to support ML-based structural design. The following description of the logic 700 is provided using the design space access engine 108 and the structural design engine 110 as examples. However, various other implementation options by systems are possible.

In implementing the logic 700, the design space access engine 108 may access a design space of a physical structure (702). In implementing the logic 700, the structural design engine 110 may encode the design space into a set of 3D rectangles (704), and each 3D rectangle may define candidate beam locations in the physical structure and the candidate beam locations of the 3D rectangles may be defined by lines between vertex pairs of each 3D rectangle. In implementing the logic 700, the structural design engine 110 may also provide the encoded design space as an input to an ML model (706) and generate, through the ML model, a design of the physical structure based on the encoded design space (708). The design of the physical structure may include beams at beam locations determined by the ML model from the candidate beam locations.

In implementing the logic 700, the structural design engine 110 may further provide the design of the physical structure in support of manufacture of the physical structure (710). As noted herein, a design of physical structure as generated through a ML model may include any number of design components, such as framework layouts, beam classifications, offset or rotation values, end-cut assignments, end-cut or joint parameters, and the like. The structural design engine 110 may provide any of these ML-generated design components in support of manufacture of the physical structure.

For instance, the structural design engine 110 may provide design data for completed designs to manufacturing facilities to be used in subsequent physical manufacture. As another example, the structural design engine 110 may provide a physical structure design (or component thereof) for further processing, e.g., by encoding and providing a generated framework layout to an ML model for beam classification determinations, providing an encoded design space that includes beam classifications to the ML model for offset or rotation value determinations, etc. As noted herein, any number of sequential design processes may be implemented or performed via ML techniques, and structural design engine 110 may provide a design generated in a first design step as an input to a next design step, and so forth. In such a manner, the ML-based structural features described herein may support any number of discrete steps in the design of beam-based physical structures.

The logic 700 shown in FIG. 7 provides an illustrative example by which a computing system 100 may support ML-based structural design of physical structures. Additional or alternative steps in the logic 700 are contemplated herein, including according to any of the various features described herein for the design space access engine 108, the structural design engine 110, the ML model 120, or any combinations thereof.

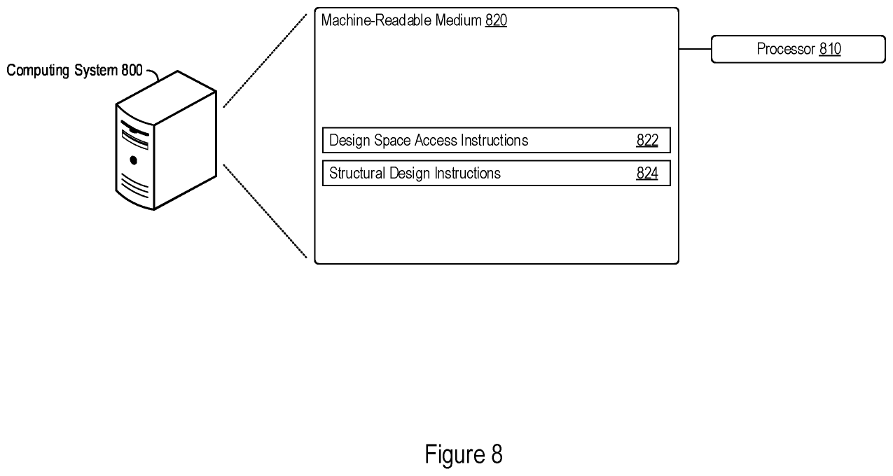

FIG. 8 shows an example of a computing system 800 that supports ML-based structural design. The computing system 800 may include a processor 810, which may take the form of a single or multiple processors. The processor(s) 810 may include a central processing unit (CPU), microprocessor, or any hardware device suitable for executing instructions stored on a machine-readable medium. The computing system 800 may include a machine-readable medium 820. The machine-readable medium 820 may take the form of any non-transitory electronic, magnetic, optical, or other physical storage device that stores executable instructions, such as the design space access instructions 822 and the structural design instructions 824 shown in FIG. 8. As such, the machine-readable medium 820 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 800 may execute instructions stored on the machine-readable medium 820 through the processor 810. Executing the instructions (e.g., the design space access instructions 822 and/or the structural design instructions 824) may cause the computing system 800 to perform any of the ML-based structural design features described herein, including according to any of the features of the design space access engine 108, the structural design engine 110, the ML model 120, or any combinations thereof.

For example, execution of the design space access instructions 822 by the processor 810 may cause the computing system 800 to access a design space of a physical structure. Execution of the structural design instructions 824 by the processor 810 may cause the computing system 800 to encode the design space into a set of 3D rectangles, and each 3D rectangle may define candidate beam locations in the physical structure and the candidate beam locations of the 3D rectangles may be defined by lines between vertex pairs of each 3D rectangle. Execution of the structural design instructions 824 by the processor 810 may also cause the computing system 800 to provide the encoded design space as an input to an ML model and generate, through the ML model, a design of the physical structure based on the encoded design space. The design of the physical structure may include beams at beam locations determined by the ML model from the candidate beam locations. Execution of the structural design instructions 824 by the processor 810 may further cause the computing system 800 to provide the design of the physical structure in support of manufacture of the physical structure.

Any additional or alternative ML-based structural design features as described herein may be implemented via the design space access instructions 822, structural design instructions 824, or a combination of both.

The systems, methods, devices, and logic described above, including the design space access engine 108 and the structural design engine 110, may be implemented in many different ways in many different combinations of hardware, logic, circuitry, and executable instructions stored on a machine-readable medium. For example, the design space access engine 108, the structural design engine 110, or combinations thereof, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the design space access engine 108, the structural design engine 110, or combinations thereof.

The processing capability of the systems, devices, and engines described herein, including the design space access engine 108 and the structural design engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more qimplementations are possible.

1. A method comprising:
by a computing system:
accessing a design space of a physical structure;
encoding the design space into a set of 3-dimensional (3D) rectangles, wherein each 3D rectangle defines candidate beam locations in the physical structure and wherein the candidate beam locations of the 3D rectangles are defined by lines between vertex pairs of each 3D rectangle;
providing the encoded design space as an input to a machine-learning (ML) model;
generating through the ML model, a design of the physical structure based on the encoded design space, wherein the design of the physical structure comprises beams at beam locations determined by the ML model from the candidate beam locations; and
providing the design of the physical structure in support of manufacture of the physical structure.

2. The method of claim 1, wherein the 3D rectangle defines a fully connected structure wherein candidate beam locations are defined between all vertex pairs of each 3D rectangle.

3. The method of claim 1, wherein providing the input to the ML model further comprises providing design parameters for the physical structure, wherein the design parameters comprise force values applicable to the physical structure, a structure type, or a combination of both.

4. The method of claim 1, wherein generating the design of the physical structure though the ML model further comprises determining a beam classification for each of the beams at the determined beam locations.

5. The method of claim 1, wherein generating the design of the physical structure though the ML model further comprises determining a beam classification for each of the beams at the determined beam locations offset or rotation values to interconnect the beams at the determined beam locations, end-cut classifications to apply at connection points between the beams at the determined beam locations or any combination thereof.

6. The method of claim 1, further comprising training the ML model, including by:
accessing a set of physical structure designs;
for a given physical structure design in the set, generating an encoded design space for the given physical structure design, wherein:
the encoded design space for the given physical structure design comprises encoded 3D rectangles mapped to different portions of the given physical structure design;
each encoded 3D rectangle defines possible beam locations in a design space of the given physical structure design; and
each encoded 3D rectangle encodes which of the possible beam locations map to beams in the given physical structure design and which of the possible beam locations do not map to any beams in the given physical structure design; and
providing the encoded design space for the given physical structure design as training data for the ML model.

7. The method of claim 6, wherein generating the encoded design space for the given physical structure design further comprises:
extracting structure data from the given physical structure design, including a beam classification for each of the beams in the given physical structure design, offset or rotation values to interconnect the beams in the given physical structure design, end-cut classifications to apply at connection points between the beams in the given physical structure design, or any combination thereof; and
encoding the extracted structure data in the encoded design space for the given physical structure design.

8. A system comprising:
a design space access engine configured to access a design space of a physical structure; and
a structural design engine configured to:
encode the design space into a set of 3-dimensional (3D) rectangles, wherein each 3D rectangle defines candidate beam locations in the physical structure and wherein the candidate beam locations of the 3D rectangles are defined by lines between vertex pairs of each 3D rectangle;
provide the encoded design space as an input to a machine-learning (ML) model;
generate, through the ML model, a design of the physical structure based on the encoded design space, wherein the design of the physical structure comprises beams at beam locations determined by the ML model from the candidate beam locations; and
provide the design of the physical structure in support of manufacture of the physical structure.

9. The system of claim 8, wherein the 3D rectangle defines a fully connected structure wherein candidate beam locations are defined between all vertex pairs of each 3D rectangle.

10. The system of claim 8, wherein the structural design engine is configured to provide the input to the ML model further by providing design parameters for the physical structure, wherein the design parameters comprise force values applicable to the physical structure, a structure type, or a combination of both.

11. The system of claim 8, wherein the structural design engine is configured to generate the design of the physical structure though the ML model further by determining a beam classification for each of the beams at the determined beam locations.

12. The system of claim 8, wherein the structural design engine is configured to generate the design of the physical structure though the ML model further by determining a beam classification for each of the beams at the determined beam locations, offset or rotation values to interconnect the beams at the determined beam locations, end-cut classifications to apply at connection points between the beams at the determined beam locations, or any combination thereof.

13. The system of claim 8, wherein the structural design engine is further configured to train the ML model, including by:
accessing a set of physical structure designs;
for a given physical structure design in the set, generating an encoded design space for the given physical structure design, wherein:
the encoded design space for the given physical structure design comprises encoded 3D rectangles mapped to different portions of the given physical structure design;
each encoded 3D rectangle defines possible beam locations in a design space of the given physical structure design; and
each encoded 3D rectangle encodes which of the possible beam locations map to beams in the given physical structure design and which of the possible beam locations do not map to any beams in the given physical structure design; and
providing the encoded design space for the given physical structure design as training data for the ML model.

14. The system of claim 13, wherein the structural design engine is configured to generate the encoded design space for the given physical structure design further by:
extracting structure data from the given physical structure design, including a beam classification for each of the beams in the given physical structure design, offset or rotation values to interconnect the beams in the given physical structure design, end-cut classifications to apply at connection points between the beams in the given physical structure design, or any combination thereof; and
encoding the extracted structure data in the encoded design space for the given physical structure design.

15. A non-transitory machine-readable medium comprising instructions that, when executed by a processor, cause a computing system to:
access a design space of a physical structure;
encode the design space into a set of 3-dimensional (3D) rectangles, wherein each 3D rectangle defines candidate beam locations in the physical structure and wherein the candidate beam locations of the 3D rectangles are defined by lines between vertex pairs of each 3D rectangle;
provide the encoded design space as an input to a machine-learning (ML) Model:
generate, through the ML model, a design of the physical structure based on the encoded design space, wherein the design of the physical structure comprises beams at beam locations determined by the ML model from the candidate beam locations; and
provide the design of the physical structure in support of manufacture of the physical structure.

16. The non-transitory machine-readable medium of claim 15, wherein the 3D rectangle defines a fully connected structure wherein candidate beam locations are defined between all vertex pairs of each 3D rectangle.

17. The non-transitory machine-readable medium of claim 15, wherein the instructions, when executed, cause the computing system to provide the input to the ML model further by providing design parameters for the physical structure, wherein the design parameters comprise force values applicable to the physical structure, a structure type, or a combination of both.

18. The non-transitory machine-readable medium of claim 15, wherein the instructions, when executed, cause the computing system to generate the design of the physical structure though the ML model further by determining a beam classification for each of the beams at the determined beam locations, offset or rotation values to interconnect the beams at the determined beam locations, end-cut classifications to apply at connection points between the beams at the determined beam locations, or any combination thereof.

19. The non-transitory machine-readable medium of claim 15, wherein the instructions, when executed, cause the computing system to train the ML model, including by:
accessing a set of physical structure designs;
for a given physical structure design in the set, generating an encoded design space for the given physical structure design, wherein:
the encoded design space for the given physical structure design comprises encoded 3D rectangles mapped to different portions of the given physical structure design;
each encoded 3D rectangle defines possible beam locations in a design space of the given physical structure design; and
each encoded 3D rectangle encodes which of the possible beam locations map to beams in the given physical structure design and which of the possible beam locations do not map to any beams in the given physical structure design; and
providing the encoded design space for the given physical structure design as training data for the ML model.

20. The non-transitory machine-readable medium of claim 19, wherein the instructions, when executed, cause the computing system to generate the encoded design space for the given physical structure design further by:
extracting structure data from the given physical structure design, including a beam classification for each of the beams in the given physical structure design, offset or rotation values to interconnect the beams in the given physical structure design, end-cut classifications to apply at connection points between the beams in the given physical structure design, or any combination thereof; and
encoding the extracted structure data in the encoded design space for the given physical structure design.
